(19) United States
(12) Patent Application Publication
(10) Pub. No.: US 2025/0284863 A1
(43) Pub. Date: Sep. 11, 2025

(54) INFORMATION PROCESSING APPARATUS, INFORMATION PROCESSING METHOD, AND COMPUTER-READABLE RECORDING MEDIUM

(71) Applicant: NEC Corporation, Tokyo (JP)

(72) Inventors: Yoshiyuki YAJIMA, Tokyo (JP); Takahiro Kumura, Tokyo (JP)

(73) Assignee: NEC Corporation, Tokyo (JP)

(21) Appl. No.: 19/019,621

(22) Filed: Jan. 14, 2025

(30) Foreign Application Priority Data
Mar. 6, 2024 (JP) 2024-033866

(51) Int. Cl. G06F 30/25

(52) U.S. Cl. CPC G06F 30/25

(57) ABSTRACT

An information processing apparatus includes; a data obtaining unit that obtains an average velocity of a particle flow to be simulated; a position estimation unit that estimates respective positions of particles constituting the particle flow using the obtained average velocity, based on an assumption that distances between the particles are equal; a velocity estimation unit that estimates respective velocities of the particles so as to minimize variance of the velocities of the particles; and an output unit that outputs the estimated positions and velocities of the particles.

### CROSS-REFERENCE TO RELATED APPLICATIONS

This application is based upon and claims the benefit of priority from Japanese patent application No. 2024-033866, filed on Mar. 6, 2024, the disclosure of which is incorporated herein in its entirety by reference.

### BACKGROUND OF THE INVENTION

### 1. Field of the Invention

The present disclosure relates to a technique for setting initial conditions for simulating a flow of particles (hereinafter, referred to as a “particle flow”).

### 2. Background Art

In recent years, various simulations have been executed for analysis, optimization, and future prediction. In order to execute a simulation, it is necessary to create a model that accurately reproduces an actual situation. In addition, in creation of such a model, initial conditions are set based on data measured in the real world (hereinafter, referred to as “observation data”), but, at this time, data that could not be measured in the real world (hereinafter, referred to as “unmeasured data”) may be required. In such a case, there is a need to estimate unmeasured data, and set optimum initial conditions.

Patent Document 1 discloses an apparatus for optimizing initial conditions when executing a simulation. The apparatus disclosed in Patent Document 1 repeats setting and updating unmeasured data for initial conditions such that the difference between observation data and simulation data decreases, thereby optimizing the initial conditions.
Patent Document 1: International Patent Application Publication No. WO 2023/042612

However, in order for the apparatus disclosed in the above Patent Document 1 to optimize the initial conditions, it is necessary to repeat complicated calculation processing a large number of times, and thus there is the problem in that the efficiency of optimization is low and it takes too long.

### SUMMARY OF INVENTION

An example object of the present disclosure is to efficiently optimize initial conditions for a simulation of a particle flow.

In order to achieve the above-described object, an information processing apparatus includes:
a data obtaining unit configured to obtain an average velocity of a particle flow to be simulated;
a position estimation unit configured to estimate respective positions of particles constituting the particle flow using the obtained average velocity, based on an assumption that distances between the particles are equal;
a velocity estimation unit configured to estimate respective velocities of the particles so as to minimize variance of the velocities of the particles; and
an output unit configured to output the estimated positions and velocities of the particles.

In order to achieve the above-described object, an information processing method includes:
a data obtaining step for obtaining an average velocity of a particle flow to be simulated;
a position estimation step for estimating respective positions of particles constituting the particle flow using the obtained average velocity, based on an assumption that distances between the particles are equal;
a velocity estimation step for estimating respective velocities of the particles so as to minimize variance of the velocities of the particles; and
an output step for outputting the estimated positions and velocities of the particles.

In order to achieve the above-described object, a computer readable recording medium according to an example aspect of the invention is a computer readable recording medium that includes recorded thereon a program,
the program including instructions that cause a computer to carry out:
a data obtaining step of obtaining an average velocity of a particle flow to be simulated;
a position estimation step of estimating respective positions of particles constituting the particle flow using the obtained average velocity, based on an assumption that distances between the particles are equal;
a velocity estimation step of estimating respective velocities of the particles so as to minimize variance of the velocities of the particles; and
an output step of outputting the estimated positions and velocities of the particles.

As described above, according to the invention, it is possible to efficiently optimize initial conditions for a simulation of a particle flow.

### BRIEF DESCRIPTION OF THE DRAWINGS

FIG. 1 is a configuration diagram showing an exemplary configuration of the information processing apparatus.

FIG. 2 is a configuration diagram showing the exemplary configuration of the information processing apparatus in more detail.

FIG. 3 is a flowchart showing an example of operations of the information processing apparatus.

FIG. 4 is a diagram conceptually showing an example of a traffic flow.

FIG. 5 is a diagram showing an example of the relationship between the average velocity and the average density of vehicles.

FIG. 6 is a diagram showing an example of output results.

FIG. 7 is a block diagram illustrating an example of a computer that realizes the information processing apparatus.

### EXAMPLE EMBODIMENT

### Example Embodiment

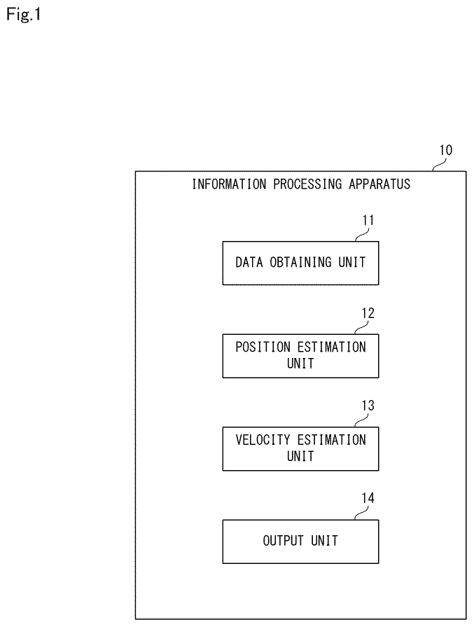

An information processing apparatus, an information processing method, and a program according to an example embodiment will be described below with reference to FIGS. 1 to 7.

### [Apparatus Configuration]

First, an exemplary schematic configuration of an information processing apparatus will be described with reference to FIG. 1. FIG. 1 is a configuration diagram showing an exemplary configuration of the information processing apparatus.

An information processing apparatus 10 shown in FIG. 1 is an apparatus for setting initial conditions for a simulation of flow of particles (particle flow). The information processing apparatus 10 is also an initial condition setting apparatus. As shown in FIG. 1, the information processing apparatus 10 includes a data obtaining unit 11, a position estimation unit 12, a velocity estimation unit 13, and an output unit 14.

The data obtaining unit 11 obtains an average velocity of a particle flow to be simulated. The position estimation unit 12 estimates the respective positions of the particles constituting the particle flow on the assumption that the distances between the particles are equal.

The velocity estimation unit 13 estimates the respective velocities of the particles that minimize the variance of the velocities of the particles. The output unit 14 outputs the estimated positions and velocities of the particles.

In this manner, the information processing apparatus 10 can estimate the positions and velocities of particles that are used as initial conditions for a simulation, without repeating complicated calculation processing a large number of times. The information processing apparatus 10 makes it possible to efficiently optimize initial conditions for a simulation of particle flow.

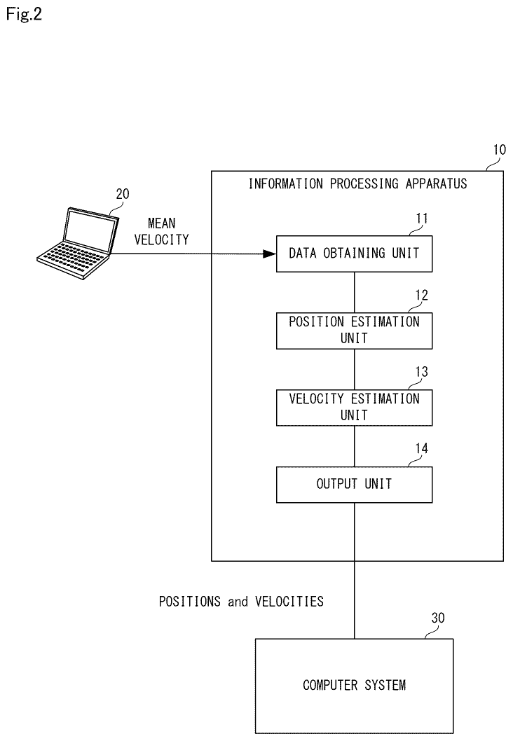

Next, a configuration and functions of the information processing apparatus 10 will be described in detail with reference to FIG. 2. FIG. 2 is a configuration diagram showing the exemplary configuration of the information processing apparatus in more detail.

As shown in FIG. 2, the information processing apparatus 10 is connected to a terminal apparatus 20 and a computer system 30 via a network or the like.

The computer system 30 generates a model of particle flow using initial conditions (the positions and the velocities of particles) output by the information processing apparatus 10, and executes a simulation of particle flow using the generated model.

The user inputs the average velocity of a particle flow, which is actual data of a simulation, via the terminal apparatus 20. In the example embodiment, the data obtaining unit 11 obtains the average velocity of the particle flow input from the terminal apparatus.

In the example embodiment, the position estimation unit 12 first obtains the average density of the particle flow using the relationship between the average velocities and the average densities of particle flows, which was obtained in advance. Furthermore, the position estimation unit 12 obtains the total number of particles based on the average density of the particles. Next, the position estimation unit 12 estimates the respective positions of the particles using the obtained total number of particles such that the above assumption that “the distances between the particles constituting the particle flow are equal” holds true.

In the example embodiment, the velocity estimation unit 13 first estimates a plurality of possible velocities of the particles, using the obtained average velocity in accordance with a predetermined rule so as to minimize the variance of the velocities. The rule has been set in the simulation or model that is applied.

Next, the velocity estimation unit 13 determines, for each of the particles, one of the plurality of estimated velocities as a velocity thereof so as to minimize the variance of the velocities of the particles in the particle flow. The result of this determination is a result of estimating a velocity of each particle.

The output unit 14 outputs the positions of the particles estimated by the position estimation unit 12 and the velocities of the particles estimated by the velocity estimation unit 13, to the computer system 30. Accordingly, the computer system executes a simulation of the particle flow.

### [Apparatus Operations]

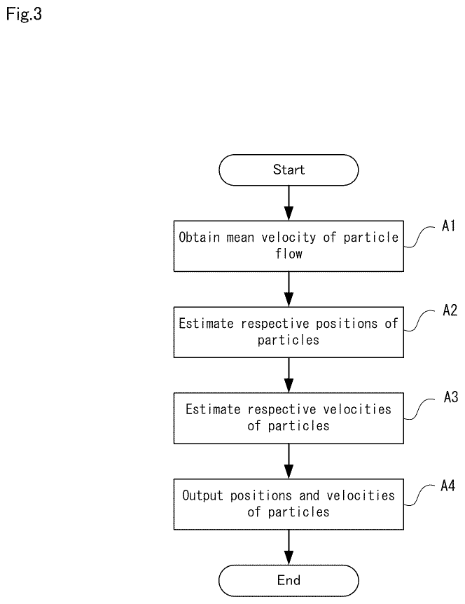

Next, an example of operations of the information processing apparatus 10 will be described with reference to FIG. 3. FIG. 3 is a flowchart showing an example of operations of the information processing apparatus. In the following description, FIGS. 1 and 2 are referenced as appropriate. In addition, in the example embodiment, an information processing method is performed by operating the information processing apparatus 10. Thus, the following description of operations of the information processing apparatus is given in place of a description of the information processing method according to the example embodiment.

As shown in FIG. 3, first, the data obtaining unit 11 obtains the average velocity of a particle flow to be simulated, via the terminal apparatus 20 (step A1).

Next, the position estimation unit 12 estimates the respective positions of particles using the obtained average velocity, on the assumption that the distances between the particles constituting the particle flow are equal (step A2).

Specifically, in step A2, the position estimation unit 12 first applies the average velocity obtained in step A1 to the relationship between the average velocities and the average densities of particle flows, which was obtained in advance, to obtain the average density of the particle flow. Furthermore, the position estimation unit 12 obtains the total number of particles based on the average density of the particle flow. The position estimation unit 12 then estimates the respective positions of the particles using the obtained number of particles based on the above assumption.

Next, the velocity estimation unit 13 estimates the respective velocities of the particles so as to minimize the variance of the velocities of the particles (step A3).

Specifically, in step A3, the velocity estimation unit 13 first estimates a plurality of possible velocities of the particles, using the average velocity obtained in step A1 in accordance with a rule set in advance. The velocity estimation unit 13 then determines, for each of the particles, one of the plurality of estimated velocities as the velocity thereof so as to minimize the variance of the velocities of the particles in the particle flow.

Thereafter, the output unit 14 outputs the positions of the particles estimated in step A2 and the velocities of the particles estimated in step A3, to the computer system 30 (step A4). After execution of step A4, the computer system 30 generates a particle flow model using, as initial conditions, the positions and the velocities of the particles output in step A4, and executes a simulation of the particle flow using the generated model.

### SPECIFIC EXAMPLES

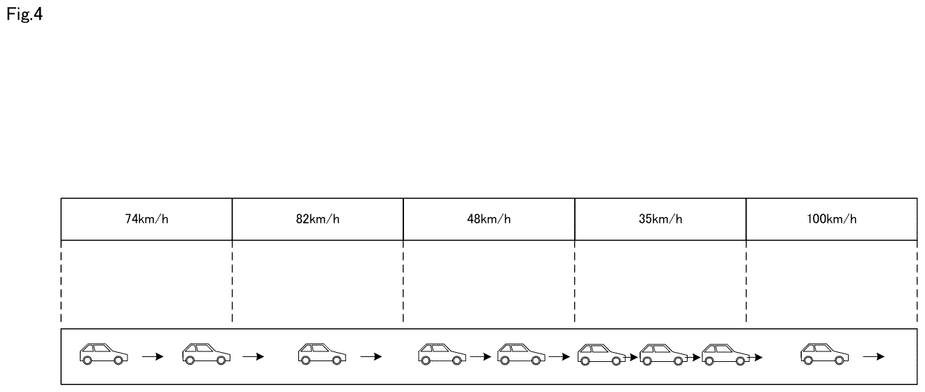

Next, a specific example of operations of the information processing apparatus 10 will be described with reference to FIGS. 4 to 6 in accordance with the steps shown in FIG. 3. In addition, an example will be described below in which the particle flow to be simulated is a flow of moving objects (vehicles) in traffic.

FIG. 4 is a diagram conceptually showing an example of a traffic flow. As shown in FIG. 4, when a road is observed for each section thereof, it is found that the density of vehicles is lower in a section where the average velocity is higher, and the density of vehicles is higher in a section where the average velocity is lower. In traffic engineering, it is known as a rule of thumb that there is a certain relationship between the average velocity and the density of vehicles. Note that the density of vehicles in this case is obtained based on the average number of vehicles in a specific road section during a specific time range. Thus, hereinafter, the density of vehicles in this case will be referred to as “average density of vehicles”.

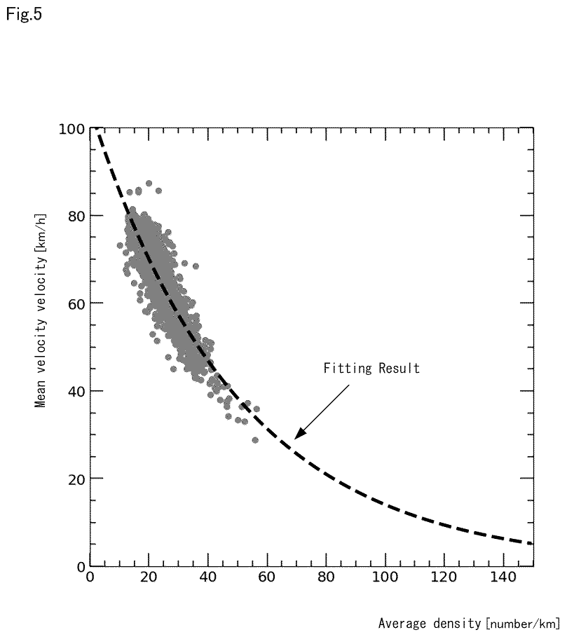

FIG. 5 is a diagram showing an example of the relationship between the average velocity and the average density of vehicles. The points plotted in FIG. 5 are actual measurement values measured on a road. The relationship between the average velocity and the average density of vehicles in traffic flow is obtained by fitting Expression 1 below to these actual measurement values. In Expression 1 below, v represents the average velocity of vehicles and k represents the average density of the vehicles. a and b are parameters that are obtained through fitting. The broken line shown in FIG. 5 is the graph of Expression 1 obtained through fitting.

$$v = a exp ( - k / b ) \qquad Expression 1$$

### Step A1

In step A1, the data obtaining unit 11 obtains the average velocity of vehicles in traffic flow as the average velocity of a particle flow to be simulated, via the terminal apparatus 20. The average velocity of the vehicles that is obtained here is a value actually measured in a specific section of a road (specific road section). The specific section is a section for which a simulation is performed.

### Step A2

In step A2, the position estimation unit 12 first substitutes the average velocity obtained in step A1 into Expression 1 above to calculate the average density of the vehicles. Furthermore, the position estimation unit 12 calculates the number of vehicles in the corresponding road section based on the average density. Next, the position estimation unit 12 estimates the positions of the vehicles using the obtained number of vehicles based on the assumption that “the distances between particles constituting the particle flow are equal”.

Specifically, the position estimation unit 12 determines the respective positions of the vehicles based on the entropy maximization principle such that the distances between vehicles are equal. When there are N vehicles in the specific section, for example, the position estimation unit 12 calculates the position xi of an i (=1, 2, . . . . N)-th vehicle by using Expression 2 below. In Expression 2 below, xₛ represents the position of the starting point of the section, and xₑ represents the position of the ending point of the section. In addition, if the target road has two or more lanes, the positions of the vehicles can be estimated by assuming the ratio of vehicles that are present in each lane, obtaining the number of vehicles present in the lane, and using the Expression 2 below for the lane.

$${x}_{i} = {x}_{s} + i ( {x}_{e} - {x}_{s} ) / ( N + 1 ) \qquad Expression 2$$

### Step A3

In step A3, the velocity estimation unit 13 estimates the respective velocities of the vehicles so as to minimize the variance of the velocities of the vehicles. In a state where the variance of the velocities is large, the likelihood of occurrence of a rear-end collision is high. On the other hand, in reality, the likelihood of occurrence of a rear-end collision is low, and thus it is assumed that the variance of the velocities is minimized as described above.

Specifically, the velocity estimation unit 13 first estimates a plurality of possible velocities of the vehicles so as to minimize the variance of the velocities of the vehicles, using the average velocity obtained in step A1 in accordance with a rule for a simulation that was set in advance.

Assume that, for example, the resolution of a velocity is set to a multiple of 20 [km/h] in a model for a simulation. In this case, this is regarded as a rule. Thus, the velocity estimation unit 13 sets the velocity to a multiple of 20 [km/h] based on the average velocity so as to minimize the variance of the velocities.

That is to say, assuming that the average velocity in a certain section is 48.5 [km/h], the velocity estimation unit 13 sets 60 [km/h] and 40 [km/h], which are multiples of 20 [km/h], as possible values of the velocity of each vehicle. Note that, in this case, if possible values are estimated to be 80 [km/h] and 20 [km/h] as the velocity of each vehicle, the variance will not be minimized, and a restriction will be violated.

Next, the velocity estimation unit 13 calculates the numbers of vehicles corresponding to the set velocities. A lower velocity of the set velocities is defined as a velocity V₁ and a higher velocity is defined as a velocity Vₕ, the total number of vehicles is defined as N, the number of vehicles travelling at the velocity Vₗ is defined as Nₗ, and the number of vehicles travelling at the velocity Vₕ is defined as Nₕ, for example.

In this case, the velocity estimation unit 13 calculates the number Ni of vehicles travelling at the velocity Vₗ and the number Nₕ of vehicles travelling at the velocity Vₕ using Expressions 3 and 4 below. In Expression 3 below, dv represents the resolution [km/h] of a velocity, and Vs represents the average velocity [km/h] obtained by the data obtaining unit 11. “round” indicates that the value is rounded. In addition, Expression 3 below is derived from a condition on which the harmonic mean of vehicle velocities coincides with the obtained average velocity when the number of vehicles travelling at the velocity Vₗ is Nₗ and the number of vehicles travelling at the velocity Vₕ is Nₕ (in traffic engineering, the average velocity of vehicles is defined by the harmonic mean of the vehicles, not the arithmetic mean of the vehicles).

$${N}_{1} = round [ {NV}_{1} ( {V}_{1} + dv - {v}_{s} ) ] / {v}_{s} dv \qquad Expression 3$$

$${N}_{h} = N - {N}_{1} \qquad Expression 4$$

Furthermore, assume that, in the case where the above average velocity is 48.5 [km/h] and 60 [km/h] and 40 [km/h] are set as the velocities of the vehicles, the distance of the section is 1 km and the average density of the vehicles is 49 [vehicles/km]. In this case, the velocity estimation unit 13 calculates the number of vehicles travelling at the velocity of 40 [km/h] as 23 and the number of vehicles travelling at the velocity of 60 [km/h] as 26 using Expressions 3 and 4 above.

The velocity estimation unit 13 then randomly provides one of the set velocities to each of the vehicles whose positions were calculated in step A2, such that the number of vehicles travelling at the provided velocity coincides with the calculated number of vehicles travelling at the velocity.

### Step A4

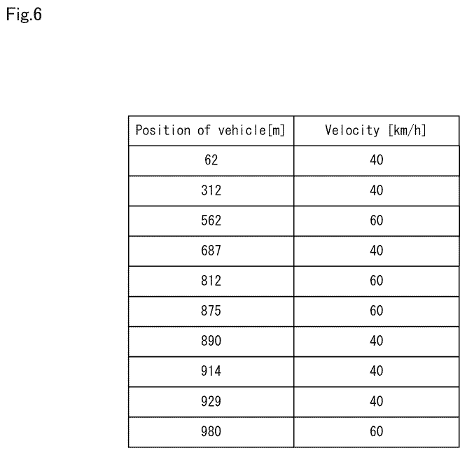

In step A4, the output unit 14 outputs the positions of the vehicles calculated in step A2 and the velocities of the vehicles calculated in step A3 to the computer system 30. FIG. 6 is a diagram showing an example of output results. Each result shown in FIG. 6 is output every minute for each section (1 km).

After execution of step A4, the computer system 30 generates a model of traffic flow using the positions and velocities of the vehicles output in step A4 as initial conditions, and executes a simulation of traffic flow using the generated model.

### Effects of Example Embodiment

As described above, in the example embodiment, the positions and velocities of vehicles in a traffic flow can be estimated without repeating complicated calculation processing a large number of times, and these can be used as initial conditions for a simulation. According to the example embodiment, it is possible to efficiently optimize the initial conditions for a simulation of traffic flow.

In addition, in the above example, a case has been described in which the particle flow is traffic flow, but the present disclosure is not limited to this example. The present disclosure can also be used to simulate various particles flowing inside pipes, ducts, and the like.

### [Program]

The program in the example embodiment need only be a program that causes a computer to execute steps A1 to A4 shown in FIG. 3. The information processing apparatus and the information processing method can be realized, by this program being installed on a computer and executed. In this case, a processor of the computer performs processing while functioning as the data obtaining unit 11, the position estimation unit 12, the velocity estimation unit 13, and the output unit 14. Examples of the computer include a general-purpose PC, server computer, as well as a smartphone and a tablet-type terminal device.

The program in the example embodiment may also be executed by a computer system constructed from a plurality of computers. In this case, for example, each computer may function as one of the data obtaining unit 11, the position estimation unit 12, the velocity estimation unit 13, and the output unit 14.

### [Physical Configuration]

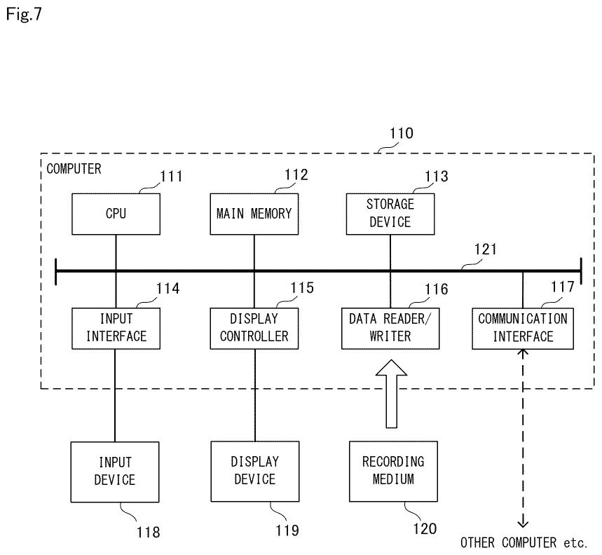

Here, a computer that realizes the information processing apparatus 10 by executing the program will be described with reference to FIG. 7. FIG. 7 is a block diagram illustrating an example of a computer that realizes the information processing apparatus.

As illustrated in FIG. 11, a computer 110 includes a CPU 111, a main memory 112, a storage device 113, an input interface 114, a display controller 115, a data reader/writer 116, and a communication interface 117. These units are connected via a bus 121 so as to be able to perform data communication with each other.
the computer 110 may include a GPU (Graphics Processing Unit) or a FPGA (Field-Programmable Gate Array) in addition to the CPU 111 or instead of the CPU 111. In this case, the GPU or the FPGA may execute the program.

The CPU 111 loads programs (codes) according to the present example embodiment stored in the storage device 113 to the main memory 112, and executes the programs in a predetermined order to perform various kinds of calculations. The main memory 112 is typically a volatile storage device such as a DRAM (Dynamic Random Access Memory).

Also, the program according to the present example embodiment is provided in the state of being stored in a computer-readable recording medium 120. Note that programs according to the present example embodiment may be distributed on the Internet that is connected via the communication interface 117.

Specific examples of the storage device 113 include a hard disk drive, and a semiconductor storage device such as a flash memory. The input interface 114 mediates data transmission between the CPU 111 and an input device 118 such as a keyboard or a mouse. The display controller 115 is connected to a display device 119 and controls the display of the display device 119.

The data reader/writer 116 mediates data transmission between the CPU 111 and the recording medium 120, reads out programs from the recording medium 120, and writes the results of processing performed by the computer 110 to the recording medium 120. The communication interface 117 mediates data transmission between the CPU 111 and another computer.

Specific examples of the recording medium 120 include general-purpose semiconductor storage devices such as a CF (Compact Flash (registered trademark)) and a SD (Secure Digital), a magnetic recording medium such as a flexible disk, and an optical recording medium such as a CD-ROM (Compact Disk Read Only Memory).

Note that the information processing apparatus can also be realized by using hardware (for example, electronic circuits) corresponding to the units, in place of a computer that has programs installed therein. Furthermore, a configuration may also be adopted in which a portion of the information processing apparatus is realized by programs, and the remaining portion of the information processing apparatus is realized by hardware. In the example embodiment, the computer is not limited to the computer illustrated in FIG. 7.

One or all of the above-described example embodiments can be expressed as, but are not limited to, Supplementary Note 1 to Supplementary Note 12 described below.

### Supplementary Note 1

An information processing apparatus comprising:
a data obtaining unit configured to obtain an average velocity of a particle flow to be simulated;
a position estimation unit configured to estimate respective positions of particles constituting the particle flow using the obtained average velocity, based on an assumption that distances between the particles are equal;
a velocity estimation unit configured to estimate respective velocities of the particles so as to minimize variance of the velocities of the particles; and
an output unit configured to output the estimated positions and velocities of the particles.

### Supplementary Note 2

The information processing apparatus according to supplementary note 1,
wherein the position estimation unit obtains an average density of the particle flow, using a previously obtained relationship between average velocities and average densities of particle flows, further obtains the total number of particles in the particle flow based on the obtained average density of the particle flow, and estimates the respective positions of the particles by using the obtained total number of particles based on the assumption.

### Supplementary Note 3

The information processing apparatus according to supplementary note 1,
wherein the velocity estimation unit estimates a plurality of possible velocities of the particles, using the obtained average velocity in accordance with a rule set in advance, and determines, for each of the particles, one of the plurality of possible velocities as a velocity thereof so as to minimize variance of the velocities of the particles in the particle flow.

### Supplementary Note 4

The information processing apparatus according to supplementary note 1,
wherein the particle flow to be simulated is a flow of moving objects in traffic.

### Supplementary Note 5

An information processing method comprising:
a data obtaining step for obtaining an average velocity of a particle flow to be simulated;
a position estimation step for estimating respective positions of particles constituting the particle flow using the obtained average velocity, based on an assumption that distances between the particles are equal;
a velocity estimation step for estimating respective velocities of the particles so as to minimize variance of the velocities of the particles; and
an output step for outputting the estimated positions and velocities of the particles.

### Supplementary Note 6

The information processing method according to supplementary note 5,
wherein, in the position estimation step, an average density of the particle flow is obtained using a previously obtained relationship between average velocities and average densities of particle flows, the total number of particles in the particle flow is further obtained based on the obtained average density of the particle flow, and the respective positions of the particles are estimated by using the obtained total number of particles based on the assumption.

### Supplementary Note 7

The information processing method according to supplementary note 5,
wherein, in the velocity estimation step, a plurality of possible velocities of the particles are estimated using the obtained average velocity in accordance with a rule set in advance, and one of the plurality of possible velocities is determined, for each of the particles, as a velocity thereof so as to minimize variance of the velocities of the particles in the particle flow.

### Supplementary Note 8

The information processing method according to supplementary note 5,
wherein the particle flow to be simulated is a flow of moving objects in traffic.

### Supplementary Note 9

A computer-readable recording medium on which a program is recorded, the program including instructions that cause a computer to carry out:
a data obtaining step of obtaining an average velocity of a particle flow to be simulated;
a position estimation step of estimating respective positions of particles constituting the particle flow using the obtained average velocity, based on an assumption that distances between the particles are equal;
a velocity estimation step of estimating respective velocities of the particles so as to minimize variance of the velocities of the particles; and
an output step of outputting the estimated positions and velocities of the particles.

### Supplementary Note 10

The computer-readable recording medium according to supplementary note 9,
wherein, in the position estimation step, an average density of the particle flow is obtained using a previously obtained relationship between average velocities and average densities of particle flows, the total number of particles in the particle flow is further obtained based on the obtained average density of the particle flow, and the respective positions of the particles are estimated by using the obtained total number of particles based on the assumption.

### Supplementary Note 11

The computer-readable recording medium according to supplementary note 9,
wherein, in the velocity estimation step, a plurality of possible velocities of the particles are estimated using the obtained average velocity in accordance with a rule set in advance, and one of the plurality of possible velocities is determined, for each of the particles, as a velocity thereof so as to minimize variance of the velocities of the particles in the particle flow.

### Supplementary Note 12

The computer-readable recording medium according to supplementary note 9,
wherein the particle flow to be simulated is a flow of moving objects in traffic.

Although the invention of the present application has been described above with reference to the example embodiment, the invention of the present application is not limited to the above-described example embodiment. Various changes that can be understood by a person skilled in the art within the scope of the invention of the present application can be made to the configuration and the details of the invention of the present application.

### INDUSTRIAL APPLICABILITY

As described above, according to the invention, it is possible to efficiently optimize initial conditions for a simulation of a particle flow. The present disclosure is useful for a system executing s several simulations.

### REFERENCE SIGNS LIST

10 Information processing apparatus
11 Data obtaining unit
12 Position estimation unit
13 Velocity estimation unit
14 Output unit
20 Terminal apparatus
30 Computer system
110 Computer
111 CPU
112 Main memory
113 Storage device
114 Input interface
115 Display controller
116 Data reader/writer
117 Communication interface
118 Input device
119 Display device
120 Recording medium
121 Bus

What is claimed is:

1. An information processing apparatus comprising:
at least one memory storing instructions; and
at least one processor configured to execute the instructions to:
obtain an average velocity of a particle flow to be simulated;
estimate respective positions of particles constituting the particle flow using the obtained average velocity, based on an assumption that distances between the particles are equal;
estimate respective velocities of the particles so as to minimize variance of the velocities of the particles; and
output the estimated positions and velocities of the particles.

2. The information processing apparatus according to claim 1,
wherein the one or more processors further obtains an average density of the particle flow, using a previously obtained relationship between average velocities and average densities of particle flows, further obtains the total number of particles in the particle flow based on the obtained average density of the particle flow, and estimates the respective positions of the particles by using the obtained total number of particles based on the assumption.

3. The information processing apparatus according to claim 1,
wherein the one or more processors further estimates a plurality of possible velocities of the particles, using the obtained average velocity in accordance with a rule set in advance, and determines, for each of the particles, one of the plurality of possible velocities as a velocity thereof so as to minimize variance of the velocities of the particles in the particle flow.

4. The information processing apparatus according to claim 1,
wherein the particle flow to be simulated is a flow of moving objects in traffic.

5. An information processing method comprising:
obtaining an average velocity of a particle flow to be simulated;
estimating respective positions of particles constituting the particle flow using the obtained average velocity, based on an assumption that distances between the particles are equal;
estimating respective velocities of the particles so as to minimize variance of the velocities of the particles; and
outputting the estimated positions and velocities of the particles.

6. The information processing method according to claim 5,
wherein, in the position estimation, an average density of the particle flow is obtained using a previously obtained relationship between average velocities and average densities of particle flows, the total number of particles in the particle flow is further obtained based on the obtained average density of the particle flow, and the respective positions of the particles are estimated by using the obtained total number of particles based on the assumption.

7. The information processing method according to claim 5,
wherein, in the velocity estimation, a plurality of possible velocities of the particles are estimated using the obtained average velocity in accordance with a rule set in advance, and one of the plurality of possible velocities is determined, for each of the particles, as a velocity thereof so as to minimize variance of the velocities of the particles in the particle flow.

8. The information processing method according to claim 5,
wherein the particle flow to be simulated is a flow of moving objects in traffic.

9. A non-transitory computer-readable recording medium on which a program is recorded, the program including instructions that cause a computer to carry out:
obtaining an average velocity of a particle flow to be simulated;
estimating respective positions of particles constituting the particle flow using the obtained average velocity, based on an assumption that distances between the particles are equal;
estimating respective velocities of the particles so as to minimize variance of the velocities of the particles; and
outputting the estimated positions and velocities of the particles.

10. The non-transitory computer-readable recording medium according to claim 9,
wherein, in the position estimation, an average density of the particle flow is obtained using a previously obtained relationship between average velocities and average densities of particle flows, the total number of particles in the particle flow is further obtained based on the obtained average density of the particle flow, and the respective positions of the particles are estimated by using the obtained total number of particles based on the assumption.

11. The non-transitory computer-readable recording medium according to claim 9,
wherein, in the velocity estimation, a plurality of possible velocities of the particles are estimated using the obtained average velocity in accordance with a rule set in advance, and one of the plurality of possible velocities is determined, for each of the particles, as a velocity thereof so as to minimize variance of the velocities of the particles in the particle flow.

12. The non-transitory computer-readable recording medium according to claim 9,
wherein the particle flow to be simulated is a flow of moving objects in traffic.
